(19) United States
(12) Patent Application Publication
(10) Pub. No.: US 2022/0329288 A1
(43) Pub. Date: Oct. 13, 2022

(54) ELECTRONIC DEVICE USING NEAR FIELD COMMUNICATION

(71) Applicant: Qisda Corporation, Taoyuan City (TW)

(72) Inventor: Shih-Min HSIANG, Taoyuan City (TW)

(73) Assignee: Qisda Corporation, Taoyuan City (TW)

(21) Appl. No.: 17/699,249

(22) Filed: Mar. 21, 2022

(30) Foreign Application Priority Data
Apr. 8, 2021 (CN) 202110376113.1

(51) Int. Cl. H04B 5/00

(52) U.S. Cl. CPC H04B 5/0081

(57) ABSTRACT

An electronic device using near field communication is provided. The electronic device using near field communication includes a coil element, a display module, an antenna element and a switch element. The display module includes a panel. The antenna element is configured to transmit and receive a near field communication signal. The coil element, the display module and the antenna element are stacked. The coil element and the antenna element are at least partially overlapped. The switch element is connected to the coil element. The switch element is configured to switch the coil element into an open-loop state or a closed-loop state.

This application claims the benefit of People's Republic of China application Serial No. 202110376113.1, filed Apr. 8, 2021, the subject matter of which is incorporated herein by reference.

### BACKGROUND OF THE INVENTION

### Field of the Invention

The invention relates in general to an electronic device, and more particularly to an electronic device using near field communication.

### Description of the Related Art

In a conventional electronic device using near field communication technique for sensing, normally the near field communication antenna is disposed above one of the display panels. However, the said design is disadvantaged by having an antenna sensing area protruded from the display surface of the electronic device, not only jeopardizing the appearance but also limiting the display area. Therefore, it has become a prominent task for the industries to provide an electronic device using near field communication whose near field communication antenna is disposed under the display panel.

### SUMMARY OF THE INVENTION

According to one embodiment of the present invention, an electronic device using near field communication is provided. The electronic device using near field communication comprises a coil element, a display module, an antenna element and a switch element. The display module includes a panel. The antenna element is configured to transmit and receive a near field communication signal. The coil element, the display module and the antenna element are stacked. The coil element and the antenna element are at least partially overlapped. The switch element is connected to the coil element. The switch element is configured to switch the coil element into an open-loop state or a closed-loop state.

According to another embodiment of the present invention, an electronic device using near field communication is provided. The electronic device using near field communication comprises a coil element, a display module, an antenna element and a controller. The display module includes a panel. The antenna element is configured to transmit and receive a near field communication signal. The coil element, the display module and the antenna element are stacked. The coil element and the antenna element are at least partially overlapped. The controller is connected to the display module and the antenna element. The controller receives a fresh rate signal from the display frame of the panel. At a first time point when the panel refreshes the frame, the controller controls the antenna element to stop transmitting and receiving the near field communication signal. At a second time point when the panel does not refresh the frame, the controller controls the antenna element to transmit and receive the near field communication signal.

According to an alternate embodiment of the present invention, an electronic device using near field communication is provided. The electronic device using near field communication comprises a coil element, a display module, an antenna element and a controller. The display module includes a panel. The antenna element is configured to transmit and receive a near field communication signal. The coil element, the display module and the antenna element are stacked. The coil element and the antenna element are at least partially overlapped. The controller is connected to the display module and the antenna element. In response to that the antenna element transmits and receives the near field communication signal, the controller controls the display module to reduce a fresh rate of the display frame of the panel.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of an electronic device in an open-loop state according to an embodiment of the present invention.

FIG. 2 is a block diagram of an electronic device according to an embodiment of the present invention.

FIG. 3 is a schematic diagram of an electronic device in an open-loop state according to an embodiment of the present invention.

### DETAILED DESCRIPTION OF THE INVENTION

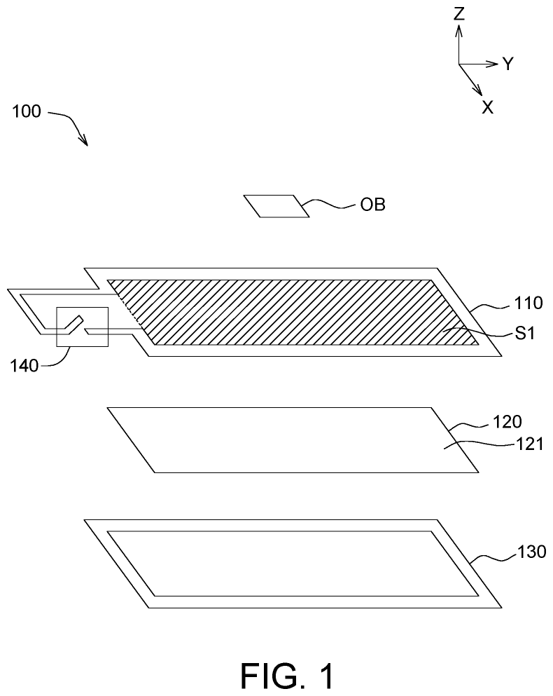

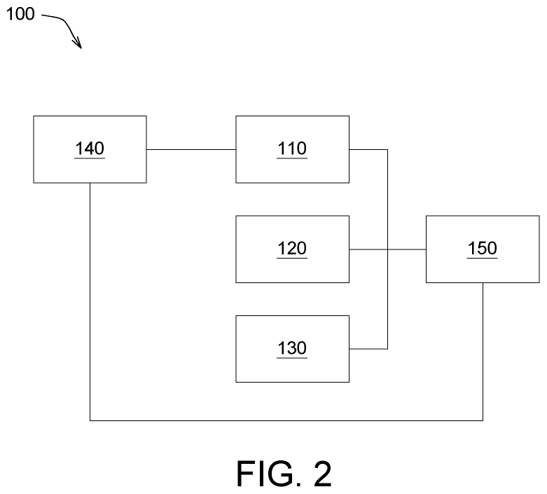

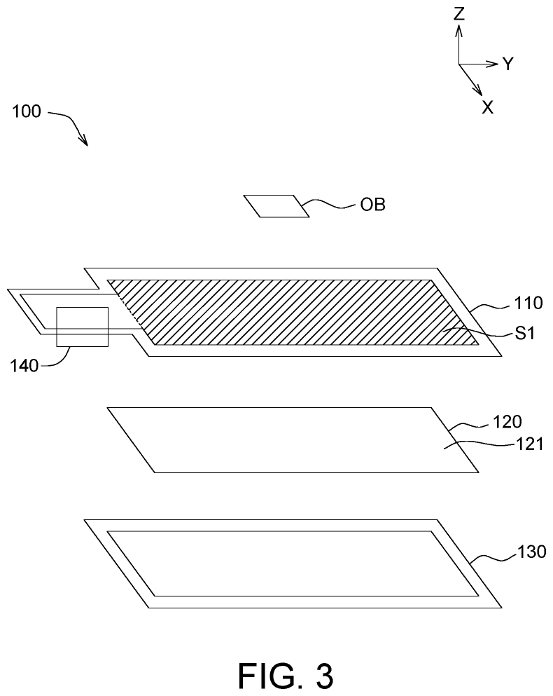

Please refer to FIG. 1 to FIG. 3. FIG. 1 is a schematic diagram of an electronic device 100 using near field communication (NFC) in an open-loop state according to an embodiment of the present invention. FIG. 2 is a block diagram of an electronic device 100 according to an embodiment of the present invention. FIG. 3 is a schematic diagram of an electronic device 100 in an open-loop state according to an embodiment of the present invention.

As indicated in FIGS. 1 and 3, the electronic device 100 mainly includes a coil element 110, a display module 120, an antenna element 130 and a switch element 140. The coil element 110, the display module 120 and the antenna element 130 are stacked along a Z-axis direction. The coil element 110 and the antenna element 130 are at least partially overlapped. Here, “are at least partially overlapped” means that projections of the elements are at least partially overlapped along a direction. In the present example, the projections of the coil element 110 and the antenna element 130 are at least partially overlapped along the Z-axis direction (that is, covers the range of complete overlapping). The switch element 140 is connected to the coil element 110.

Besides, the coil element 110 surrounds the panel 121, but the disposition of the coil element 110 is not limited thereto. That is, the coil element 110 depicts an area larger than the panel 121 on the X-Y plane. Additionally, the antenna element 130 can be disposed under the coil element 110 and the display module 120 along the Z-axis direction but the disposition of the antenna element 130 is not limited thereto. The coil element 110, such as a metal coil, forms a ground surface S1 to provide an electro-static protection effect to the electronic device 100, wherein the ground surface S1 is substantially perpendicular to the Z-axis direction. The display module 120, such as a liquid crystal display module, includes a liquid crystal panel 121, which can be selectively bonded to another touch pad to become a touch display module. The display module 120 can also be realized by other types of display module, such as an organic light emitting diode (OLED) display module or a plasma display module.

As the electronic device 100 uses the near field communication technique, the antenna element 130 is realized by a near field communication (NFC) antenna configured to transmit and receive a near field communication signal. The switch element 140, such as a loop switch, is configured to switch the coil element 110 into an open-loop state or a closed-loop state. As indicated in FIG. 1, the switch element 140 switches the coil element 110 into an open-loop state. As indicated in FIG. 3, the switch element 140 switches the coil element 110 into a close-loop state. The coil element 110 can provide an electro-static protection effect to the electronic device 100 regardless the coil element 110 is in an open-loop state or a close-loop state, but the electro-static protection effect provided in the close-loop state is better.

The functions of the electronic device 100 according to an embodiment of the present invention are disclosed below. When the coil element 110 is in a close-loop state, the coil element 110 can provide a better electro-static protection effect to the electronic device 100. However, when the coil element 110 is in a close-loop state, the emission energy of the near field communication signal will be absorbed by the closed coil element 110, hence affecting the emission quality of signal. Thus, with the disposition of the switch element 150, when the antenna element 130 needs to emit a near field communication signal, as indicated in FIG. 1, the switch element 140 switches the coil element 110 into an open-loop state to assure the emission quality of the near field communication signal. When the near field communication signal is not needed, as indicated in FIG. 3, the switch element 140 switches the coil element 110 into a close-loop, so that a better electro-static protection effect can be provided.

Please refer to FIG. 2. Specifically, the electronic device 100 may further include a controller 150 configured to control the above functions. The controller 150 is connected to the display module 120, the antenna element 130 and the switch element 140. As indicated in FIG. 1, when an object OB (such as a card supporting NFC sensing) is close to the electronic device 100 (such as NFC sensing device) to perform a contactless payment, the near field communication signal received by the antenna element 130 must have sufficient quality, so that the electronic device 100 can communicate with the card. Meanwhile, in response to that the object OB supporting near field communication is close to the electronic device 100, the controller 150 controls the switch element 140 to switch the coil element 110 into an open-loop state, so that NFC sensing can be smoothly performed.

Alternatively, in another condition, the electronic device 100 can take an initiative to request near field communication sensing, and display a specific frame (such as showing “Please keep the payment instrument close to the device”) on the panel 121 of the display module 120 to remind the payer to put the card supporting NFC sensing near the electronic device 100. Meanwhile, in response to that the panel 121 displays the specific frame, the controller 150 controls the switch element 140 to switch the coil element 110 into an open-loop state, so that NFC sensing can be smoothly performed.

When the object supporting NFC sensing communicates with the electronic device, noise interference coming from the panel of the display module can be measured. Normally, the frequency of the noises is identical to the fresh rate of the display frame of the panel. The electronic device 100 of the present invention has a distinctive design for resolving the noise problem. That is, the controller 150 receives a fresh rate signal (such as VSYNC signal) from the display frame of the panel 121, and controls the antenna element 130 to stop transmitting and receiving the near field communication signal at a first time point when the panel 121 refreshes the frame.

Furthermore, at a second time point when the panel 121 does not refresh the frame, the controller 150 controls the antenna element 130 to transmit and receive the near field communication signal. Thus, the controller 150 can obtain the refresh cycle of the frame according to the fresh rate signal received from the panel 121, and when the panel 121 refreshes the frame, the controller 150 can stop the transmission of the near field communication signal to avoid the noise interference coming from the panel 121. Then, the near field communication signal is transmitted at other time points when the frame is not refreshed, so that the communication quality of the near field communication signal can be improved. In response to that the antenna element 130 stops transmitting and receiving the near field communication signal, the controller 150 can control the switch element 140 to switch the coil element 110 into a closed-loop state, so that a better electro-static protection effect can be provided to the electronic device 100.

Or, when the controller 150 cannot smoothly obtain the refresh cycle of the frame according to the fresh rate signal received from the panel 121, another design can be used to reduce the noise interference coming from the panel 121 of the display module 12. The higher the fresh rate of the display frame of the panel, the larger the noise interference. Conversely, the lower the fresh rate of the frame, the smaller the noise interference. Thus, in response to that the antenna element 130 transmits and receives the near field communication signal, the controller 150 can control the display module 120 to reduce the fresh rate of the display frame of the panel 121 to reduce the noise interference coming from the panel 121, so that the communication quality of the near field communication signal can be improved.

To summarize, according to the electronic device using near field communication of the present invention, the antenna element using near field communication is disposed under the panel, and through the design of the switch element, the coil element which provides electro-static protection is switched according to the transmission and reception of the near field signal, so that the energy of the near field signal will not be absorbed by the coil element, the near field signal can be smoothly transmitted, and the coil element can provide better electro-static protection when there is no need to use the near field signal for transmission.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device using near field communication, comprising:
a coil element;
a display module including a panel;
an antenna element configured to transmit and receive a near field communication signal, wherein the coil element, the display module and the antenna element are stacked, and the coil element and the antenna element are at least partially overlapped; and
a switch element connected to the coil element, wherein the switch element is configured to switch the coil element into an open-loop state or a closed-loop state.

2. The electronic device according to claim 1, wherein the coil element forms a ground surface, the coil element and the antenna element are at least partially overlapped in a direction perpendicular to the ground surface.

3. The electronic device according to claim 2, wherein the coil element surrounds the panel, and the antenna element is disposed under the coil element and the display module along the direction.

4. The electronic device according to claim 1, further comprising:
a controller connected to the switch element, wherein in response to that an object supporting near field communication sensing is close to the electronic device, the controller controls the switch element to switch the coil element into an open-loop state.

5. The electronic device according to claim 1, further comprising:
a controller connected to the display module and the switch element, wherein in response to that the panel displays a specific frame, the controller controls the switch element to switch the coil element into an open-loop state.

6. The electronic device according to claim 1, further comprising:
a controller connected to the display module and the antenna element, wherein the controller receives a fresh rate from the display frame of the panel signal, at a first time point when the panel refreshes the frame, the controller controls the antenna element to stop transmitting and receiving the near field communication signal.

7. The electronic device according to claim 6, wherein at a second time point when the panel does not refresh the frame, the controller controls the antenna element to transmit and receive the near field communication signal.

8. The electronic device according to claim 6, wherein the controller is connected to the switch element, and in response to that the antenna element stops transmitting and receiving the near field communication signal, the controller controls the switch element to switch the coil element into a closed-loop state.

9. The electronic device according to claim 1, further comprising:
a controller connected to the display module and the antenna element, wherein in response to that the antenna element transmits and receives the near field communication signal, the controller controls the display module to reduce a fresh rate of the display frame of the panel.

10. An electronic device using near field communication, comprising:
a coil element;
a display module including a panel;
an antenna element configured to transmit and receive a near field communication signal, wherein the coil element, the display module and the antenna element are stacked, and the coil element and the antenna element are at least partially overlapped; and
a controller connected to the display module and the antenna element to receive a fresh rate signal from the display frame of the panel, wherein at a first time point when the panel refreshes the frame, the controller controls the antenna element to stop transmitting and receiving the near field communication signal, and at a second time point when the panel does not refresh the frame, the controller controls the antenna element transmits and receives the near field communication signal.

11. The electronic device according to claim 10, wherein the coil element forms a ground surface, and the coil element and the antenna element are at least partially overlapped in a direction perpendicular to the ground surface.

12. The electronic device according to claim 11, wherein the antenna element is disposed under the coil element and the display module along the direction.

13. The electronic device according to claim 10, further comprising:
a switch element connected to the coil element and configured to switch the coil element into an open-loop state or a closed-loop state.

14. The electronic device according to claim 10, wherein the controller is connected to the switch element, and in response to that an object supporting near field communication sensing is close to the electronic device, the controller controls the switch element to switch the coil element into an open-loop state.

15. The electronic device according to claim 10, wherein the controller is connected to the switch element, and in response to that the panel displays a specific frame, the controller controls the switch element to switch the coil element into an open-loop state.

16. The electronic device according to claim 10, wherein the controller is connected to the switch element, and in response to that the antenna element stops transmitting and receiving the near field communication signal, the controller controls the switch element to switch the coil element into a closed-loop state.

17. An electronic device using near field communication, comprising:
a coil element;
a display module including a panel;
an antenna element configured to transmit and receive a near field communication signal, wherein the coil element, the display module and the antenna element are stacked, and the coil element and the antenna element are at least partially overlapped; and
a controller connected to the display module and the antenna element, wherein in response to that the antenna element receives and transmits the near field communication signal, the controller controls the display module to reduce a fresh rate of the display frame of the panel.
